(19) United States
(12) Patent Application Publication
(10) Pub. No.: US 2008/0237866 A1
(43) Pub. Date: Oct. 2, 2008

(54) SEMICONDUCTOR DEVICE WITH STRENGTHENED PADS

(75) Inventor: Wensheng WANG, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/134,625

(22) Filed: Jun. 6, 2008

Related U.S. Application Data
(63) Continuation of application No. PCT/JP2005/022545, filed on Dec. 8, 2005.

(51) Int. Cl. H01L 23/48

(52) U.S. Cl. 257/753; 257/758; 257/E23.141

(57) ABSTRACT

A semiconductor device is provided having an increased hardness against contact of a probe needle. The semiconductor device includes: a semiconductor substrate; a semiconductor element formed in the semiconductor substrate; an insulating film formed above the semiconductor substrate and covering the semiconductor element; a multilayer wiring structure formed in the insulating film; and a pad electrode structure connected to the multilayer wiring structure and formed on the insulating film, the pad electrode structure including a conductive adhesion film, a conductive pad electrode formed above the conductive adhesion film, and a conductive hydrogen barrier film formed above the conductive pad electrode.

### BACKGROUND OF THE INVENTION

A) Field of the Invention

The embodiments discussed herein are directed to a semiconductor device, which may have pads for connection to an external circuit and for inspection.

B) Description of the Related Art

A semiconductor integrated circuit device has pads on the layer same as the uppermost wiring layer or above the uppermost wiring layer. A probe needle is abutted on the pad for inspection, or wires are bonded to the pads for connection to an external circuit. The pad has a relatively large size as compared to other wiring patterns, and the upper surface is exposed on which a probe needle is abutted or to which a connection wire is bonded. Until a semiconductor integrated circuit is completed, a plurality of inspections are performed, and only the products judged good at a final stage is packaged.

As a probe needle is abutted on a pad during inspection, the pad may have a crack. Even if there is a crack, a wire can be bonded to the pad so that this device is used as a finished product. Even after wire bonding, the pad surface is in an exposed state, and moisture and/or hydrogen are likely to permeate from the crack. As the permeated moisture and/or hydrogen reach wirings and oxide, chemical reactions occur and the performance of the semiconductor device is influenced.

The development of a ferro-electric memory (FeRAM) is in progress which uses a ferro-electric capacitor and stores information by utilizing reversible polarization of ferro-electric material. A ferro-electric memory is a nonvolatile memory whose stored information will not be erased even if a power supply is shut down, and is expected to realize high integration, high speed driving, high durability and low power consumption.

A ferro-electric memory stores information by utilizing hysteresis characteristics of ferro-electric material. A ferro-electric capacitor having a ferro-electric film as a capacitor dielectric film sandwiched between a pair of electrodes generates polarization corresponding to a voltage applied across the electrodes, and retains the polarization even after the applied voltage is removed. As the polarity of the applied voltage is reversed, the polarity of polarization is also reversed. By detecting this polarization, information can be read. As the material of a ferro-electric film, ferro-electric oxide material having a perovskite crystal structure is used mainly, such as PZT (Pb(Zr₁₋ₓTiₓ)O₃) and SBT (SrBi₂Ta₂O₉) having a large polarization quantity, e.g., about 10 μC/cm² to 30 μC/cm². In order to form a ferro-electric oxide film having excellent characteristics, the film is required to be formed or to be subjected to heat treatment in an oxidizing atmosphere, and a lower electrode (also an upper electrode when necessary) is often made of noble metal hard to be oxidized, noble metal maintaining conductivity even if it is oxidized, or noble metal oxide.

Before a ferro-electric capacitor is formed, a MOS transistor is formed on a silicon substrate. When a ferro-electric capacitor is formed after conductive plugs of W or the like connected to the transistor are formed, it is necessary that an oxidizing atmosphere during the formation of the ferro-electric film should not adversely affect the lower structure.

The interlayer insulating film of a semiconductor integrated circuit device is made of silicon oxide in many cases. Silicon oxide has high affinity with moisture. As moisture permeates from an external, moisture can reach wirings, capacitors, transistors and the like through the interlayer insulating film. As moisture reaches a capacitor particularly a ferro-electric capacitor, the characteristics of a dielectric film particularly a ferro-electric film are deteriorated. If the ferro-electric film is reduced by hydrogen derived from permeated moisture and oxygen defects are formed, crystallinity becomes bad. The characteristics are deteriorated such as a reduced residual polarization quantity and a lowered dielectric constant. Similar phenomena occur by long term use. As hydrogen permeates, deterioration of the characteristics becomes more direct than moisture. Silane used as silicon source for forming a silicon film or a silicon oxide film is silicon hydride, and generates hydrogen when decomposed. Such hydrogen is also a factor of deteriorating a ferro-electric film.

In a manufactured semiconductor integrated circuit device, the region most influenced by externally permeating moisture and hydrogen is considered to be pads and their nearby areas. For example, although an interlayer insulating film such as a silicon oxide film, a silicon nitride film and a polyimide film are formed covering the uppermost wirings including pads, the polyimide film, silicon nitride film and silicon oxide film on the pads are removed in order to allow electric contact with the pads. Although the silicon nitride film has an ability of shielding moisture and hydrogen, the silicon nitride film on the pads are removed so that moisture and hydrogen can directly contact the pads.

JP-A-2003-174146 (applicant: Fujitsu Limited) proposes that an upper electrode is formed by a lamination of two types of noble metal oxide films. Transistors formed on a semiconductor substrate are covered with an insulating barrier film having an oxygen shielding ability such as a silicon nitride film and an silicon oxynitride film in order to prevent an oxidizing atmosphere during formation of the ferro-electric film from adversely affecting the transistors. The ferro-electric capacitor is covered with an insulating barrier film having a hydrogen shielding ability such as alumina in order to prevent the characteristics of the ferro-electric capacitor from being degraded by heat treatment in a reducing atmosphere.

JP-A-2005-39299 (applicant: Matsushita Electric Industrial Co. Ltd.) proposes that over a ferro-electric capacitor having a structure that a ferro-electric film covers a lower electrode formed on an interlayer insulating film and an upper electrode covers the ferro-electric film, a conductive hydrogen barrier film is formed covering the upper electrode and having an overhang portion extending over the interlayer insulating film. After an upper interlayer insulating film is formed covering the ferro-electric capacitor, a via hole is formed reaching the overhang portion of the conductive hydrogen barrier film, and a conductive plug is formed in the via hole. It teaches that it is preferable to use as the conductive hydrogen barrier film a Ti film, a Ta film, a TiON film, a TiN film, a TaN film, a TiAlN film, a TiAlON film or an alloy film containing these.

JP-A-2003-86589 (applicant: Fujitsu Limited) proposes a pad structure and discloses that a pad electrode has a structure that a TiN barrier metal film is disposed on the upper and lower surfaces of an Al alloy film, and that the central region of the upper TiN barrier metal film is removed to form a contact surface exposing the Al alloy film. With this structure, the TiN barrier metal film presents an ability of shielding moisture and hydrogen.

### SUMMARY OF THE INVENTION

It is an aspect of the embodiments discussed herein to provide a semiconductor device including: a semiconductor substrate; a semiconductor element formed in the semiconductor substrate; an insulating film formed above the semiconductor substrate and covering the semiconductor element; a multilayer wiring structure formed in the insulating film; and a pad electrode structure connected to the multilayer wiring structure and formed on the insulating film, the pad electrode structure including a conductive adhesion film, a conductive pad electrode formed above the conductive adhesion film, and a conductive hydrogen barrier film formed above the conductive pad electrode.

### BRIEF DESCRIPTION OF THE DRAWINGS

FIGS. 1A to 1L are cross sectional views of a semiconductor substrate illustrating main processes of a method for manufacturing a semiconductor device according to a first embodiment.

FIG. 2 is a table showing hardness of various conductive materials.

FIG. 3 is a cross sectional view showing the semiconductor device of the first embodiment in the state of yield measurement inspection.

FIGS. 4A and 4B are cross sectional views of modifications of the first embodiment.

FIGS. 5A to 5E are cross sectional views of a semiconductor substrate illustrating main processes of a method for manufacturing a semiconductor device according to a second embodiment.

FIGS. 6A to 6F are cross sectional views of a semiconductor substrate illustrating main processes of a method for manufacturing a semiconductor device according to a third embodiment.

FIG. 7 is a cross sectional view showing another modification.

FIGS. 8A to 8D are cross sectional views showing other modifications.

### DESCRIPTION OF THE PREFERRED EMBODIMENTS

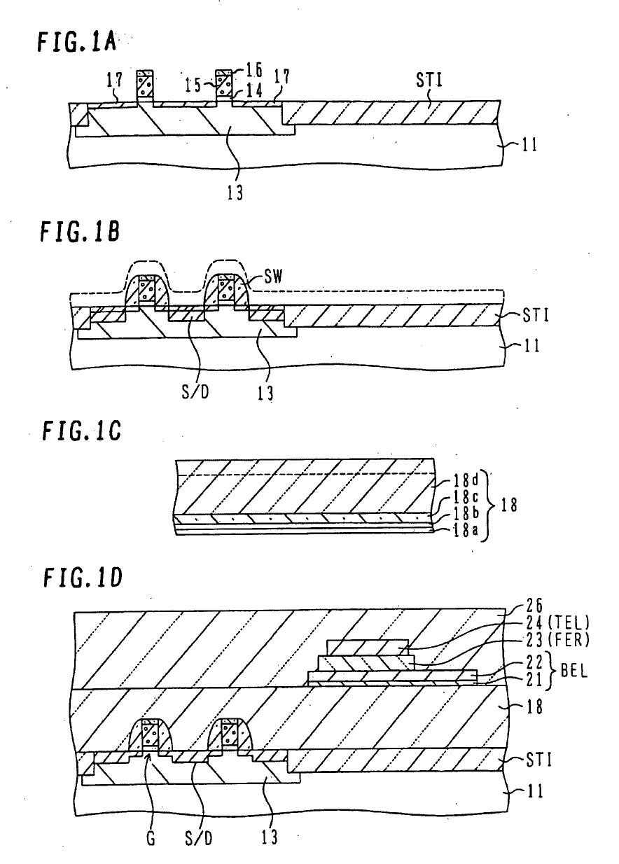

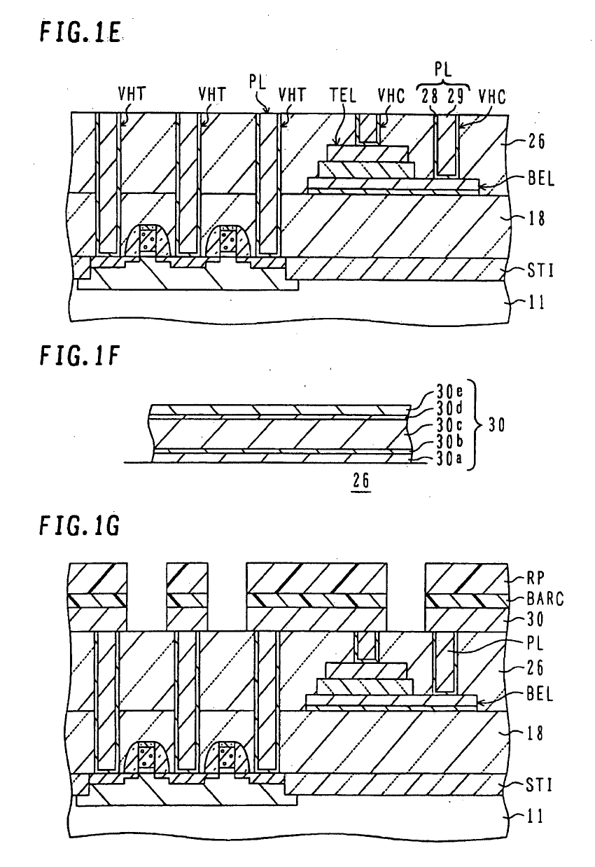

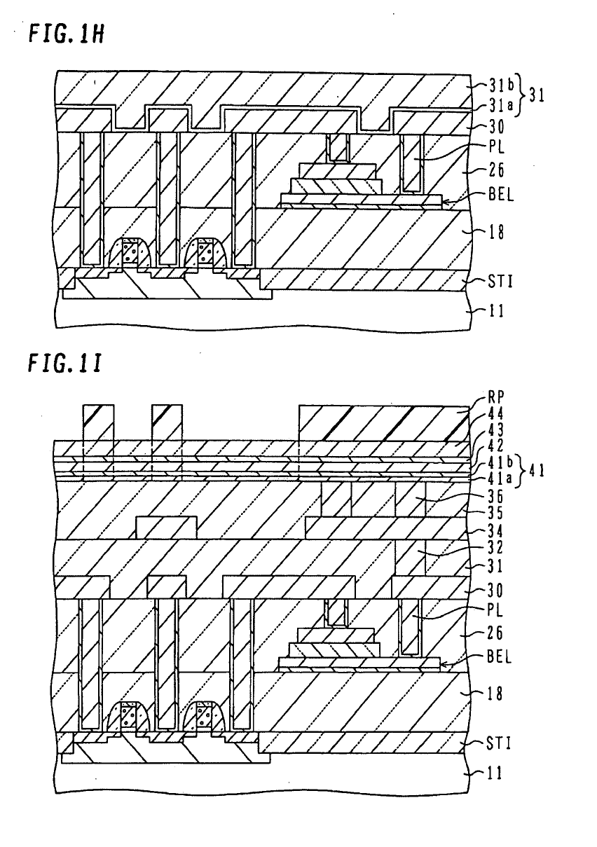

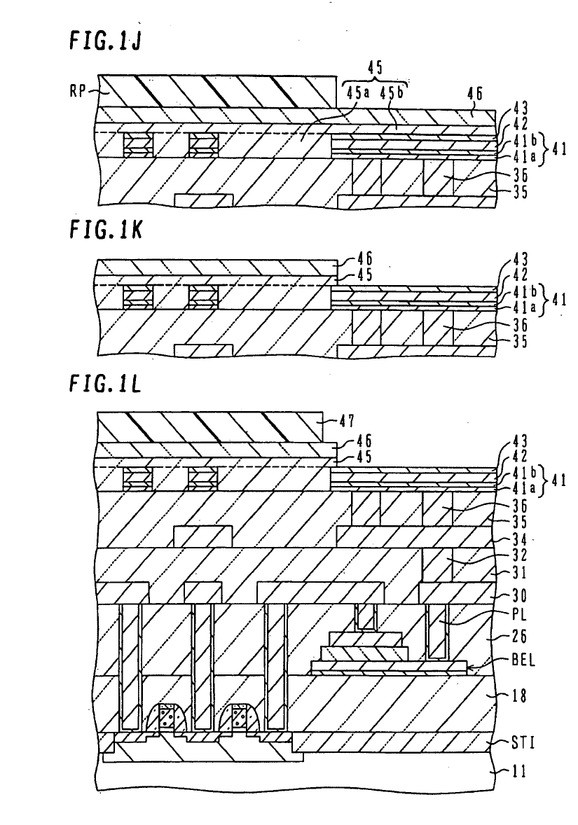

With reference to FIGS. 1A to 1L, description will be made on a method for manufacturing a semiconductor device according to the first embodiment.

As shown in FIG. 1A, in the surface layer of a semiconductor substrate 11 of an n- or p-type silicon wafer, a shallow trench isolation STI as an isolation region defining active regions is formed. For example, a shallow trench is etched in the semiconductor substrate 11 to a depth of about 300 nm, by using a CMP stopper mask such as a silicon nitride film. An undoped silicate glass (USG) film is deposited by high density plasma (HDP) chemical vapor deposition (CVD), via a liner such as a silicon oxide film and a silicon nitride film, according to necessity. Unnecessary region of the deposited film is removed by chemical mechanical polishing (CMP) utilizing the CMP stopper. The CMP stopper is then removed by etching.

Impurity ions of a p-type, e.g., B, are implanted into the active region of an n-channel transistor region at a dose of 3×10¹³cm⁻² (hereinafter denoted as 3E13) and an acceleration energy of 300 keV, to form a p-type well 13. Impurity ions of an n-type are implanted into the p-channel transistor region to form an n-type well. Description will be made hereinafter by using the n-channel transistor region by way of example. For the p-channel transistor region, conductivity types are reversed.

The surfaces of active regions are thermally oxidized to form a gate insulating film 14 of a silicon oxide film having a thickness of, e.g., about 3 nm. If the gate insulating film is thinned, nitrogen may be introduced after the silicon oxide film is formed. A gate electrode film 15 of a polysilicon film having a thickness of, e.g., about 180 nm is deposited on the gate insulating film 14 by CVD. A cap film 16 of a silicon nitride film having a thickness of, e.g., about 29 nm is formed on the gate electrode film 15 by CVD. A resist pattern having a gate electrode pattern is formed, and the cap film 16, gate electrode film 15 and gate insulating film 14 are etched to form an insulated gate electrode structure. By using the cap film 16 as a mask, n-type impurity ions, e.g., As, are implanted at a dose of 5E14 and an acceleration energy of 10 keV, to form lightly doped drain (LDD) (or extension) regions 17.

FIG. 1A shows the structure that gate electrodes of two transistors are juxtaposed. The central source/drain region (hereinafter called a source region according to necessity) of these transistors is connected to a common bit line, and a memory capacitor is connected to each of source/drain regions on the both sides (hereinafter called drain regions according to necessity). Since the structure is of a bilateral symmetry, only the right capacitor structure is shown.

As shown in FIG. 1B, for example, a silicon oxide film is deposited on the whole surface of the semiconductor substrate by CVD, covering the gate electrode structure, and etched back to leave side wall spacers SW only on side walls of the gate electrode structure. By using the cap layer 16 and side wall spacers SW as a mask, n-type impurity ions, e.g., P, are implanted four times into the active region at a dose of 5E14 and an acceleration energy of 13 keV, to form source/drain regions S/D having a higher concentration than the LDD regions and superposed upon the LDD regions 17.

An insulating lamination such as shown in FIG. 1C is deposited to form a first interlayer insulating film 18. First, a silicon oxide film 18a of a thickness of about 20 nm is deposited by CVD. Formed on and above the silicon oxide film are a silicon oxide film 18b having a thickness of about 20 nm, a silicon nitride film 18c having a thickness of about 80 nm, and a silicon oxide film 18d having a thickness of about 1000 nm deposited by plasma enhanced (PE) CVD using TEOS (tetraethoxysilane) as source material. The lowermost silicon oxide film 18a is formed by thermal CVD to protect the active region from plasma. The silicon nitride film 18c functions as a barrier film for preventing permeation of moisture and hydrogen. Thereafter, the surface of the TEOS silicon oxide film 18d is polished by CMP to planarize the surface thereof and set the total thickness to about 700 nm.

As shown in FIG. 1D, a ferro-electric capacitor is formed on the planarized first interlayer insulating film 18. For example, a conductive adhesion film 21 of a Ti film having a thickness of about 20 nm is deposited by sputtering, and a main bottom electrode film 22 of a Pt film having a thickness of about 150 nm is deposited on the conductive adhesion film by sputtering. In this manner, the bottom electrode lamination is formed. The main bottom electrode film is not limited to the Pt film. It is preferable that the main bottom electrode film is a film made of at least one material selected from a group consisting of Pt, Ir, Ru, Rh, Re, Os, Pd, oxide thereof, and SrRuO₃, or a lamination thereof.

A ferro-electric film 23 of, e.g., PZT, is deposited on the lower electrode layer to a thickness of about 200 nm by RF sputtering. After the ferro-electric film is deposited, a rapid thermal annealing (RTA) process is executed to crystallize the ferro-electric film 23. Thereafter, a top electrode layer 24 of an IrO₂ film having a thickness of, e.g., about 200 nm is deposited on the ferro-electric film 23 by reactive sputtering. The ferro-electric film is not limited to PZT, but a ferro-electric oxide film denoted by a general formula of ABO₃ may be used. Ferro-electric substance is preferably PZT, PZT slightly doped with additive such as La, Sr and Ca, BLT(Bi₄₋ₓLaₓTiO₃), SBT and Bi-containing layered compound. The top electrode layer is also not limited to IrO₂, but the top electrode layer is preferably a film made of at least one material selected from a group consisting of Pt, Ir, Ru, Rh, Re, Os, Pd, oxide thereof, and SrRuO₃, or a lamination thereof.

After the ferro-electric capacitor is formed, a second interlayer insulating film 26 is formed. For example, a TEOS silicon oxide film having a thickness of about 1400 nm is deposited by PE-CVD, and polished by CMP to a thickness of about 1000 nm. After CMP, in order to degas the second interlayer insulating film, an annealing process is executed in plasma of, e.g., N₂O.

As shown in FIG. 1E, conductive plugs PL are formed extending through the interlayer insulating film. First, via holes VHC are formed by dry etching using a resist pattern, the via holes extending through the second interlayer insulating film and reaching the bottom electrode BEL (21, 22) and top electrode TEL (24) of the ferro-electric capacitor. A diameter of the via hole is, e.g., about 0.5 μm. The top electrode TEL and bottom electrode BEL function as an etch stopper for etching the silicon oxide film. There is no problem in forming the via holes even at different levels of the top electrode TEL and bottom electrode BEL. Next, annealing for recovering damages received at the ferro-electric capacitor structure is executed for 60 minutes at 500° C., for example, in an oxygen atmosphere.

Via holes VHT for the source/drain regions of the transistors are formed. For example, the second interlayer insulating film 26 and first interlayer insulating film 18 are etched by dry etching using a resist mask, by using the silicon surfaces of the source/drain regions as an etch stopper. A diameter of the via hole VHT is, e.g., about 0.3 μm.

After the via holes VHC and VHT are formed, in order to remove the oxide film possibly formed on the silicon surfaces, an RF pre-process is performed, for example, about 10 nm thickness based on equivalent silicon oxide film etching. In succession, a TiN underlying glue film 28 having a thickness of, e.g., about 75 nm is deposited by sputtering to cover the inner surfaces of the via holes. Next, a W film 29 is deposited by CVD to bury the via holes. Thereafter, the W film 29 and TiN film 28 on the second interlayer insulating film are removed by CMP by utilizing the second interlayer insulating film as a CMP stopper. In this manner, the conductive plugs PL are formed.

As shown in FIG. 1F, a first wiring 30 is formed on the second interlayer insulating film 26 formed with the conductive plugs. First, a lower barrier metal film, a wiring film and an upper barrier metal film are deposited on the whole substrate surface by sputtering or the like. As the lower barrier metal film, a Ti film 30a having a thickness of, e.g., about 60 nm and a TiN film 30b having a thickness of, e.g., about 30 nm are formed. As the wiring film, an AL alloy (e.g., Al—Cu) film 30c having a thickness of, e.g., about 360 nm is formed. As the upper barrier metal layer, a Ti film 30d having a thickness of, e.g., about 5 nm and a TiN film 30e having a thickness of e.g., about 70 nm are formed. This wiring structure is the same as that of a logic circuit of the same design rule, and can guarantee high reliability.

As shown in FIG. 1G, an SiON film or an organic antireflection film BARC having a similar composition to that of resist is formed as a bottom antireflection film on the first wiring film structure, and a resist pattern RP is formed on the bottom antireflection film. By using the resist pattern RP as an etching mask, the bottom antireflection film BARC and wiring film 30 are etched to form a first wiring pattern. Thereafter, the resist pattern RP and bottom antireflection film BARC are removed, for example, by ashing. The first wiring may also be formed of a damascene wiring made of Cu or Cu alloy.

As shown in FIG. 1H, an insulating barrier film 31a having a hydrogen shielding ability is formed covering the first wiring pattern 30. The insulating barrier film 31a suppresses damages of the ferro-electric capacitor by succeeding processes, and is formed by depositing a metal oxide film having a hydrogen shielding ability, e.g., an alumina film having a thickness of, e.g., about 200 nm, by sputtering. In succession, a silicon oxide film having a thickness of about 700 nm is formed on the insulating barrier film 31a, and then a TEOS silicon oxide film is formed by PE-CVD to obtain a total thickness of about 1100 nm. Thereafter, the surface is polished by CMP to form a silicon oxide insulating film 31b having a thickness of about 700 nm. The insulating barrier film 31a and silicon oxide film 31b are collectively called a third interlayer insulating film 31 in some cases for the convenience of description.

As shown in FIG. 11, conductive plugs 32 are formed through the third interlayer insulating film 31 to derive the first wiring. First, a resist pattern having openings corresponding to connection areas of the first wiring is formed, and then via holes having a diameter of about 0.25 μm are formed extending through the third interlayer insulating film 31 and reaching the first wiring 30. Manufacture processes for the conductive plugs are similar to those for the conductive plugs PL shown in FIG. 1E.

A second wiring 34 is formed on the third interlayer insulating film 31 formed with the conductive plugs 32. Manufacture processes for the second wiring are similar to those for the first wiring described with reference to FIGS. 1F and 1G. A fourth interlayer insulating film 35 is formed covering the second wiring 34. The fourth interlayer insulating film 35 can be formed by processes similar to those for the third interlayer insulating film 31. However, the insulating barrier film may be omitted. Conductive plugs 36 extending through the fourth interlayer insulating film 35 and reaching the second wiring 34 are formed by processes similar to those for the conductive plugs 32. The number of layers of a multilayer wiring structure may be selected as desired.

A conductive adhesion film 41, a high hardness wiring film 42 and a conductive hydrogen barrier film 43 are formed on and above the whole surface of the fourth interlayer insulating film 35 formed with the conductive plugs 36. For example, a Ti film 41a having a thickness of about 30 nm and a TiAlN film 41b having a thickness of about 50 nm are formed by sputtering, to form a conductive adhesion film 41. The conductive adhesion film is a film for improving adhesion between the lower interlayer insulating film and upper wiring film, and is not limited to the TiAlN/Ti lamination. The conductive adhesion film can be formed by a single film made of at least one film selected from a Ti film, a TiN film, a TiAlN film, an Ir film, an IrOₓ film, a Pt film, an Ru film, an RuOₓ film, an Os film and a Ta film, or a multilayer film thereof.

As the high hardness wiring film 42, an Ir film having a thickness of, e.g., 200 nm is formed. Ir has a resistivity lower than that of Al—Cu. At a thickness of about 100 to 200 nm, a wiring film having a conductivity similar to that of Al—Cu having a thickness of about 350 nm can be formed. Although depending upon a film forming method, even if IrO is used instead of Ir, a conductivity of a similar level can be obtained. The high hardness wiring film is a film having a hardness rare to form a crack even if a probe needle is abutted on the pad, and is not limited only to an Ir film and an IrO film. The high hardness wiring film can be formed by a single film made of at least one material selected from a group consisting of high hardness noble metal (Ir, Ru, Rh, Re, Os), alloy thereof and oxide thereof, or a multilayer film thereof.

As the conductive hydrogen barrier film 43, a TiAlN film having a thickness of, e.g., 100 nm is formed. As compared to TiN, TiAlN is hard to be oxidized, has a barrier function against oxygen, is hard to be stripped or peeled off, has a hardness higher than TiN, and has a barrier function also against hydrogen to the same degree as TiN. In place of a conventional TiN film having a thickness of about 50 nm, a TiAlN film having a thickness of about 20 to 100 nm can be used. A rigid conductive film can be formed having an improved barrier function. If the thickness is thinner than 20 nm, a sufficient barrier function is hard to be obtained, whereas if the thickness is thicker than 100 nm, cost increases. The conductive hydrogen barrier film has a conductivity and a hydrogen barrier function, and is not limited to TiAlN. The conductive hydrogen barrier film can be formed by a single film made of nitride or oxynitride of Ti, TiAl, Ta or TaAl or mixture thereof, or a multilayer film thereof.

For example, Ir, IrOₓ, Ru, RuOₓ and Os can be used as the material of both the conductive adhesion film and high hardness wiring film. In this case, the conductive adhesion film and high hardness wiring film may have an integral structure. A strength and barrier function of the whole pad electrode structure is determined by each constituent layer. For example, if the conductive adhesion film and conductive barrier film are made of the same material, the barrier function, strength and the like can be estimated from a film having a total sum of thicknesses of two films. The strength and barrier function can therefore be considered as the performance of the whole lamination structure.

A silicon oxide film 44 having a thickness of, e.g., 800 nm is deposited on the conductive hydrogen barrier film 43, the silicon oxide film functioning also as a hard mask when the pad electrode structure is etched. A resist pattern RP is formed on the silicon oxide film 44, and by using the resist pattern as an etching mask, the silicon oxide film 44 is etched to form a hard mask. By using this hard mask, the conductive hydrogen barrier film 43, high hardness wiring film 42 and conductive adhesion film 41 are etched by using Ar+Cl₂ as etching gas. This etching may be performed by using a thick resist pattern as an etching mask without using the hard mask. Thereafter, the resist pattern RP and silicon oxide film 44 are removed. In this manner, a third wiring is formed including the pad electrode structure.

As shown in FIG. 1J, a fifth interlayer insulating film and an upper protection film are formed covering the third wiring. For example, a TEOS silicon oxide film 45a is deposited by CVD, burying the third wiring, and CMP is performed using the third wiring as a stopper to planarize the surface. Since the third wiring is exposed at this stage, an insulating film, e.g., a TEOS silicon oxide film 45b, is further deposited by CVD to form a fifth interlayer insulating film 45 having a thickness of 100 nm as measured on the third wiring.

On the fifth interlayer insulating film, an upper protection film 46 having a moisture/hydrogen shielding ability, e.g., a silicon nitride film having a thickness of 350 nm, is deposited. A resist pattern RP to be used for opening a contact area of the pad electrode structure is formed on the upper protection film 46. An opening of the resist pattern RP has a shape included or encompassed within the pad electrode as viewed in plan in order not to etch the insulating film on the side wall of the pad electrode. By using the resist pattern RP as an etching mask, the upper protection film 46 and fifth interlayer insulating film 45 are dry etched. Thereafter, the resist pattern RP is removed by ashing or the like.

As shown in FIG. 1K, the pad electrode structure is therefore completed whose main portion is exposed and whose peripheral area is covered with the fifth interlayer insulating film and upper protection film.

As shown in FIG. 1L, a polyimide film 47 having a thickness of, e.g., about 3300 nm is coated and patterned to surround the opening for the pad electrode. If photosensitive polyimide is used, this patterning is performed by exposure and development. In this manner, the semiconductor device having ferro-electric memories can be manufactured.

In this embodiment, the conductive adhesion film improves adhesion between the interlayer insulating film and uppermost wiring film, and in addition, has an excellent barrier function against moisture and hydrogen so that deterioration of the ferro-electric capacitor can be reduced effectively.

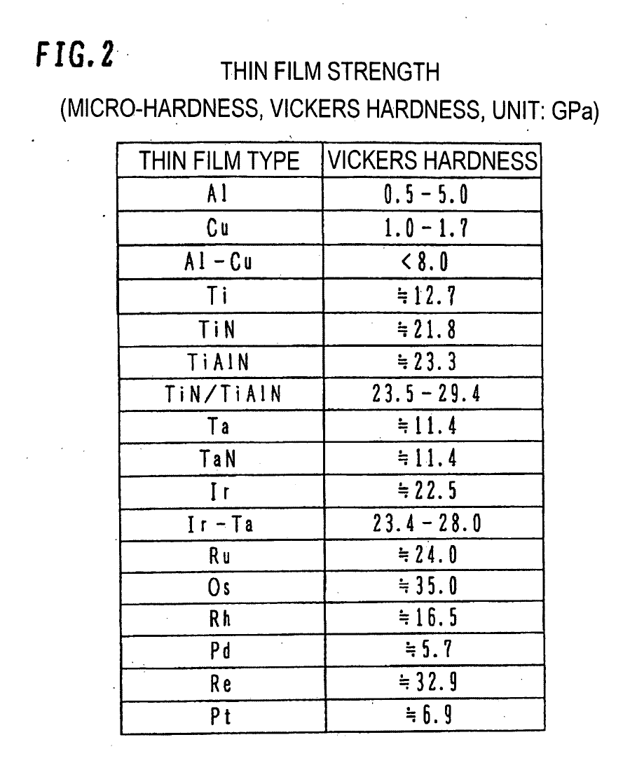

FIG. 2 is a table showing hardness of various materials. Ir, Ru, Rh, Re and Os used as the material of the high hardness wiring film 42 have a much higher hardness than that of Al and Al—Cu often used, for example, for pad wiring material. TiN, TiAlN and TaN usable as the material of the conductive hydrogen barrier film have a higher hardness than that of Al and Cu. TaAlN has also a high hardness although not shown in the table. Ti, TiN, TiAlN, Ir, Ru, Os and Ta used as the material of the conductive adhesion film have also a high hardness.

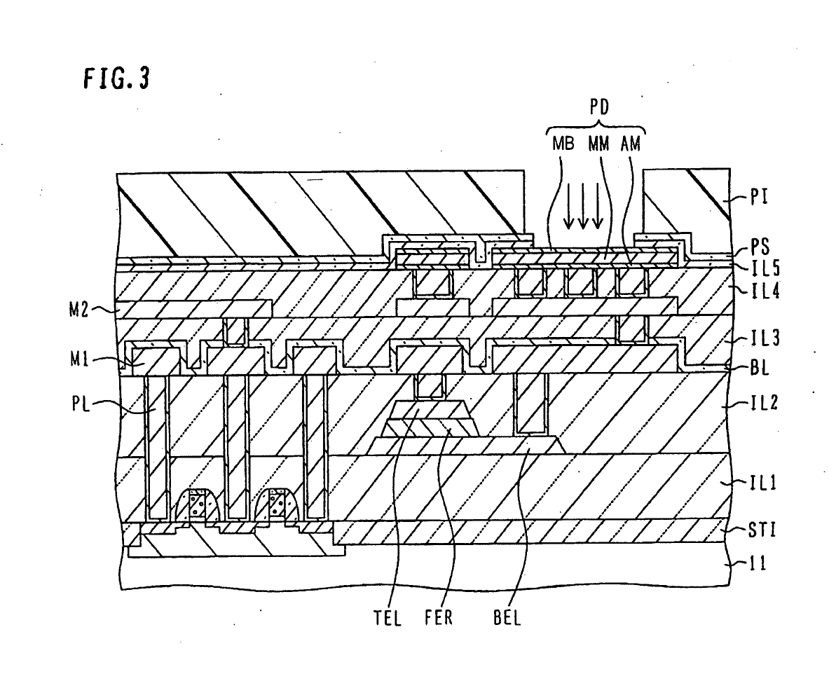

FIG. 3 is a cross sectional view showing the semiconductor device of the first embodiment in the state of yield measurement inspection. The first, second, third, fourth and fifth interlayer insulating films are denoted by IL1, IL2, IL3, IL4 and IL5, respectively. The insulating barrier film is denoted by BL, and the upper protection film is denoted by PS. The metal wiring layers excluding the pad wiring are denoted by M1 and M2. The conductive plug is denoted by PL. The polyimide film is denoted by PI. The pad electrode structure PD is constituted of the conductive adhesion film AM, main pad wiring film MM and conductive hydrogen barrier MB. In this state, an accelerated inspection is performed in a high temperature and high humidity state.

Since a hardness of the pad electrode structure can be improved, a crack is difficult to be formed upon abutment of a needle upon the pad during inspection. Since a shielding ability of moisture and hydrogen is retained, it is possible to effectively prevent inner permeation of moisture and hydrogen and it is easy to maintain the characteristics of the ferro-electric capacitor. If a sufficient hardness and a moisture/hydrogen shielding ability can be obtained by the conductive adhesion film and conductive hydrogen barrier film, the pad wiring film may be made of material other than noble metal and oxide thereof.

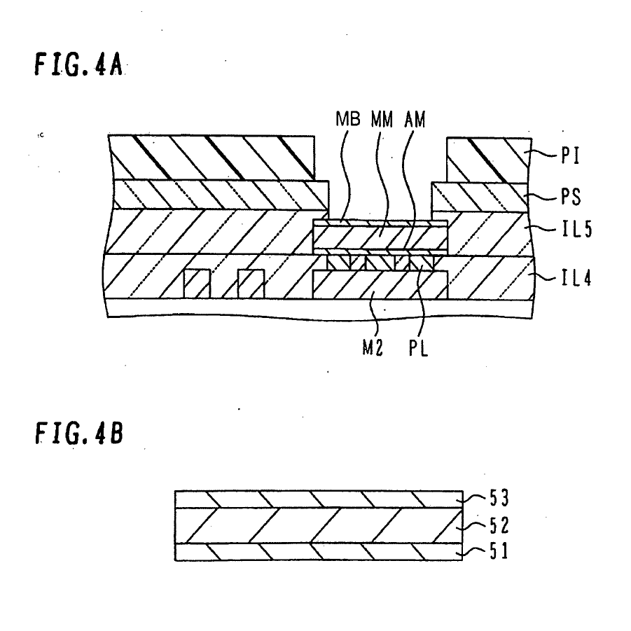

FIG. 4A shows a modification of the first embodiment. A lower pad is formed by a metal wiring film M2 as the uppermost wiring layer, and a pad electrode structure made of a lamination of a conductive adhesion film AM, a main pad electrode film MM and a conductive hydrogen barrier film MB is formed via a plurality of conductive plugs PS formed only under the pad electrode structure. The lamination structure and other structures are the same as those of the first embodiment.

FIG. 4B shows another modification. The pad electrode structure is made of a conductive adhesion film 51 similar to that of the first embodiment, an Al—Cu main pad wiring film 52, and a conductive hydrogen barrier film 53 similar to that of the first embodiment. Although the main pad wiring film 52 is made of Al alloy similar to the conventional technique, a crack is difficult to be formed because the hardness is improved by the conductive hydrogen barrier film 53 (and conductive adhesion film 51). A shielding ability for external moisture/hydrogen can be improved.

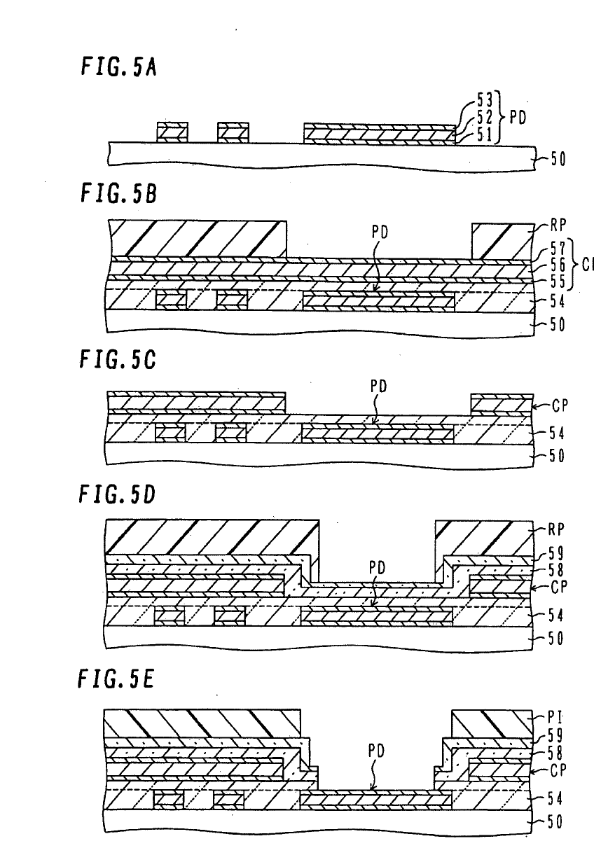

FIGS. 5A to 5E are cross sectional views of a semiconductor substrate illustrating main processes of a method for manufacturing a semiconductor device according to a second embodiment. FIG. 5A shows a state that the pad electrode structure of the modification shown in FIG. 4B is formed. The pad electrode structure PD is made of a lamination of a conductive adhesion film 51, an Al—Cu main pad electrode film 52 and a conductive hydrogen barrier film 53. An underlying structure 50 is not specifically limited, but a semiconductor device structure under the fourth interlayer insulating film of the first embodiment may be used by way of example.

As shown in FIG. 5B, the pad electrode structure is covered with a fifth interlayer insulating film 54, and the surface of this film is planarized. On the planarized fifth interlayer insulating film 54, a conductive adhesion film 55, a high hardness conductive film 56 and a conductive hydrogen barrier film 57 are stacked to form a conductive protection layer CP. The conductive adhesion film is a film for improving adhesion between the lower interlayer insulating film and upper conductive film, and is a single film having a thickness of 20 to 100 nm and made of at least one selected from a Ti film, a TiN film, a TiAlN film, an Ir film, an IrOₓ film, an Ru film, an RuOₓ film, an Os film and a Ta film, or a multilayer film thereof.

The high hardness conductive film is a film having a high hardness and a moisture/hydrogen shielding ability, and is a single film having a thickness of 20 to 100 nm and made of at least one material selected from a group consisting of high hardness noble metal (Ir, Ru, Rh, Re and Os), alloy thereof and oxide thereof, or a multilayer film thereof.

The conductive hydrogen barrier film is a film having a conductivity and a hydrogen barrier function, and is a single film having a thickness of 20 to 100 nm and made of nitride or oxynitride of Ti, TiAl, Ta or TaAl or mixture thereof, or a multilayer film thereof.

For example, Ir, IrOₓ, Ru, RuOₓ and Os can be used as the material of both the conductive adhesion film and high hardness conductive film. In this case, the conductive adhesion film and high hardness conductive film may have an integral structure. Although the above-described structure uses conductive material, a conductivity is not specifically required. TiO or AlO may be used in place of the high hardness conductive film and conductive hydrogen barrier film.

In order to remove the conductive protection film CP above the pad electrode structure, a resist pattern RP is formed on the conductive protection layer CP, and the conductive protection layer is etched.

As shown in FIG. 5C, the conductive protection layer CP is removed in the region inclusive of the pad electrode structure PD, and the resist pattern RP is thereafter removed by ashing or the like. The inner boundary of the conductive protection layer CP is spaced away from the outer boundary of the pad electrode structure PD by a predetermined distance. The pad electrode structure is maintained to be covered with the fifth interlayer insulating film 54.

As shown in FIG. 5D, an insulating film 58 and an upper protection film 59 are deposited covering the patterned conductive protection layer CP. The insulating film 58 is formed of a silicon oxide film having a thickness of, e.g., about 100 nm. The upper protection film 59 is formed of a silicon nitride film having a thickness of, e.g., about 350 nm. The insulating film 58 and upper protection film 59 form a recess above the pad electrode structure, reflecting the step of the conductive protection film. A resist pattern RP is formed on the upper protection film 59. The resist pattern RP has an opening encompassed within the recess. The upper protection film 59 at the step is covered with the resist pattern RP. By using the resist pattern RP as an etching mask, the upper protection film 59 and insulating film 58 are dry etched.

As shown in FIG. 5E, an opening is therefore formed exposing the main area of the pad electrode structure. The resist pattern RP is removed by ashing or the like. Since the upper protection film 59 is left at the step and protrudes from the step side wall, a moisture/hydrogen shielding ability can be improved. A polyimide film PI is formed on the upper protection film 59.

Since almost the whole area outside the pad is covered with the conductive protection film CP, almost the whole area of the semiconductor chip has a structure having high resistance against stress and against external permeation of moisture and hydrogen.

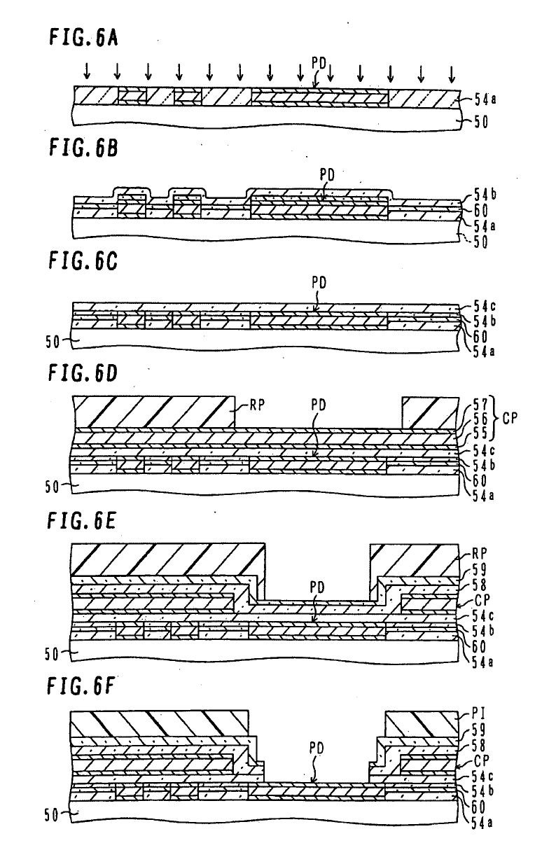

FIGS. 6A to 6F are cross sectional views of a semiconductor substrate illustrating main processes of a method for manufacturing a semiconductor device according to the third embodiment. The third embodiment has the structure that an insulating barrier film having a moisture/hydrogen shielding ability is disposed at the intermediate level of one of the multilayer wiring of the second embodiment.

As shown in FIG. 6A, on an underlying structure 50, a pad electrode structure PD is formed which has a lamination structure of a conductive adhesion film, an Al—Cu main pad electrode film and a conductive hydrogen barrier film, the pad electrode structure is covered with an insulating film 54a such as silicon oxide, and CMP is performed by using the pad electrode structure PD as a CMP stopper to planarize the surface of the insulating film. The insulating film 54a is etched back by dry etching to lower the surface of the insulating film 54a to an intermediate level of the pad electrode structure PD.

As shown in FIG. 6B, an insulating barrier film 60 having a moisture/hydrogen shielding ability such as an alumina film, a TiOₓ film, or a lamination thereof, is deposited to a thickness of about 20 nm. On the insulating barrier film 60, an insulating film 54b such as a TEOS silicon oxide film is deposited by CVD to bury the pad electrode structure PD. CMP is performed by using the pad electrode structure as a stopper to planarize the surface of the insulating film.

As shown in FIG. 6C, an insulating film 54c such as a TEOS silicon oxide film is further deposited by CVD. Thereafter, processes corresponding to those in FIGS. 5B to 5E are performed.

As shown in FIG. 6D, on the planarized insulating film 54c, a conductive adhesion film 55, a high hardness conductive film 56 and a conductive hydrogen barrier film 57 are stacked to form a conductive protection layer CP.

In order to remove the conductive protection layer CP above the pad electrode structure, a resist pattern RP is formed on the conductive protection layer CP, and the conductive protection layer CP is etched. Since almost the whole area outside the pad is covered with the conductive protection film CP, almost the whole area of the semiconductor chip has a structure having high resistance to stress and to external permeation of moisture and hydrogen.

As shown in FIG. 6E, the conductive protection layer CP in an area inclusive of the pad electrode structure is removed, and the resist pattern RP is thereafter removed by ashing or the like. The pad electrode structure is maintained to be covered with the insulating film 54c.

An insulating film 58 and an upper protection film 59 are deposited covering the patterned conductive protection layer CP. The insulating film 58 is formed by a silicon oxide film having a thickness of, e.g., about 100 nm. The upper protection film 59 is formed by a silicon nitride film having a thickness of, e.g., about 350 nm. The insulating film 58 and upper protection film 59 form a recess above the pad electrode structure, reflecting the step of the conductive protection film. A resist pattern RP is formed on the upper protection film 59. The resist pattern RP has an opening encompassed within the recess. The upper protection film 59 at the step is covered with the resist pattern RP. By using the resist pattern RP as an etching mask, the upper protection film 59 and insulating film 58 are dry etched.

As shown in FIG. 6F, an opening is therefore formed exposing the main area of the pad electrode structure. The resist pattern RP is removed by ashing or the like. Since the upper protection film 59 is left at the step and protrudes from the step side wall, a moisture/hydrogen shielding ability can be improved. A polyimide film PI is formed on the upper protection film 59.

According to the embodiment, the insulating barrier film having the moisture/hydrogen shielding ability is formed at the intermediate level of at least one of the multilayer wiring. The insulating barrier film and the wiring pattern crossing the insulating barrier film form the structure that the insulating barrier film and wiring pattern cooperatively cover the whole substrate surface. Moisture and hydrogen can be prevented more perfectly from permeating into the underlying structure. The insulating barrier film may cross the conductive plug instead of the wiring pattern.

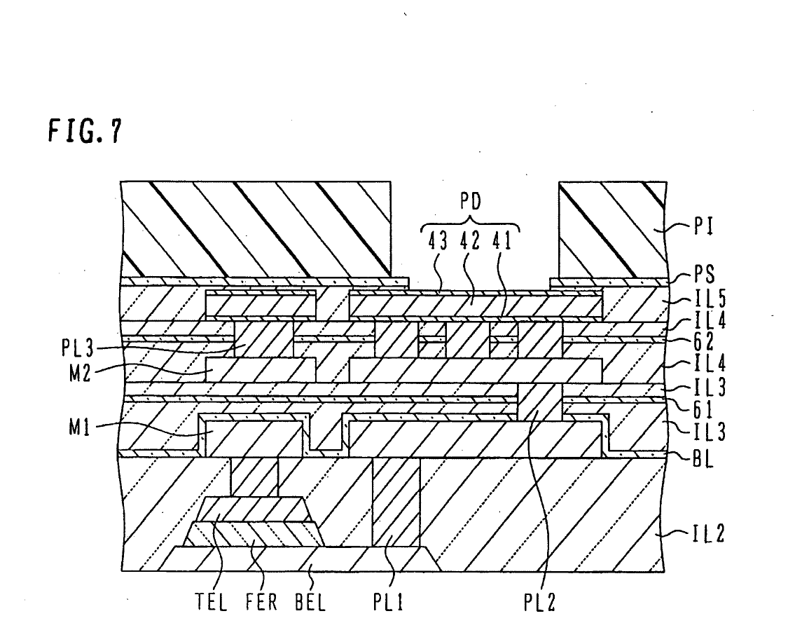

FIG. 7 is a cross sectional view showing another modification incorporating an insulating barrier film crossing a conductive plug into the first embodiment. A bottom electrode BEL, a ferro-electric film FER, and a top electrode TEL of a ferro-electric capacitor, conductive plugs PL1, PL2 and PL3, interlayer insulating films IL2, IL3, IL4 and IL5, metal wirings M1 and M2, a pad electrode structure PD, an insulating barrier film BL, an upper protection film PS and a polyimide film PI, are similar to those of the first embodiment. At the levels crossing the conductive plugs PL2 and PL3, insulating barrier films 61 and 62 are formed having a moisture/hydrogen shielding ability and made of TiO, AlO, mixture thereof or a lamination thereof.

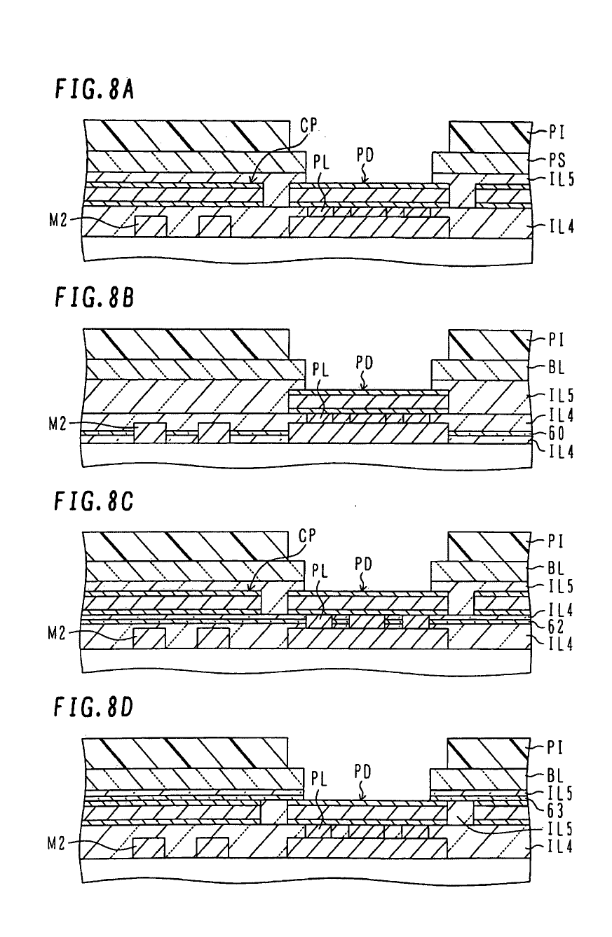

FIGS. 8A to 8D are cross sectional views showing other modifications. In these Figures, IL (IL4 and IL5) represents (fourth and fifth) interlayer insulating films, M2 represents a second metal wiring, PD represents a pad electrode structure of a lamination of a conductive adhesion film, a pad main wiring film and a conductive hydrogen barrier film similar to the first embodiment, PS represents an upper protection film made of silicon nitride, PI represents a polyimide film, and PL represents a conductive plug.

In FIG. 8A, at the same time when a pad electrode structure PD of the first embodiment is formed, a conductive protection film CP analogous to that of the second embodiment is formed by the same lamination structure. The pad electrode structure and conductive protection film are electrically isolated by trenches. The conductive protection film can be formed without increasing the number of processes.

In FIG. 8B, an insulating barrier film 60 is formed at a level crossing the second metal wiring M2.

In FIG. 8C, an insulating barrier film 62 is formed at a level crossing a conductive plug PL interconnecting a second metal wiring and a pad electrode structure.

In FIG. 8D, an insulating barrier film 63 is formed at a level flush with the upper surfaces of the pad electrode structure PD and conductive protection film CP shown in FIG. 8A. With this structure, moisture and hydrogen permeating from the upper region will not enter the lower region unless moisture and hydrogen permeate through one of the insulating barrier film 63, pad electrode structure PD and conductive protection film CP. Similar advantages can be obtained by disposing the insulating barrier film at a level crossing the pad electrode and conductive protection film.

The present invention has been described in connection with the preferred embodiments. The invention is not limited only to the above embodiments. It will be apparent to those skilled in the art that other various modifications, improvements, combinations, and the like can be made.

What are claimed are:

1. A semiconductor device comprising:
a semiconductor substrate;
a semiconductor element formed in said semiconductor substrate;
an insulating film formed above said semiconductor substrate and covering said semiconductor element;
multilayer wiring structure formed in said insulating film; and
a pad electrode structure connected to said multilayer wiring structure and formed on said insulating film, said pad electrode structure including a conductive adhesion film, a conductive pad electrode formed above said conductive adhesion film, and a conductive hydrogen barrier film formed above said conductive pad electrode.

2. The semiconductor device according to claim 1, wherein said conductive pad electrode includes a layer made of at least one material selected from a group consisting of Ir, Ru, Rh, Re, Os and oxide thereof.

3. The semiconductor device according to claim 1, wherein said conductive pad electrode includes a layer made of at least one material selected from a group consisting of Al, Cu, W and alloy thereof.

4. The semiconductor device according to claim 1, further comprising a capacitor formed above said semiconductor substrate and including a bottom electrode, a dielectric oxide film and a top electrode, wherein said multilayer wiring structure is disposed above said capacitor.

5. The semiconductor device according to claim 4, wherein said dielectric oxide film is a film made of ferro-electric substance represented by a general formula of ABO₃.

6. The semiconductor device according to claim 5, wherein said ferro-electric substance is one of PZT, PZT sightly doped with additive, BLT, SBT and Bi-containing layered compound.

7. The semiconductor device according to claim 4, wherein said bottom electrode includes a film made of at least one material selected from a group consisting of Pt, Ir, Ru, Rh, Re, Os, Pd, oxide thereof and SrRuO₃.

8. The semiconductor device according to claim 4, wherein said top electrode includes a film made of at least one material selected from a group consisting of Pt, Ir, Ru, Rh, Re, Os, Pd, oxide thereof and SrRuO₃.

9. The semiconductor device according to claim 1, wherein said conductive hydrogen barrier film includes a layer of one of nitride and oxynitride of Ti, TiAl, Ta and TaAl and mixture thereof or a lamination thereof.

10. The semiconductor device according to claim 1, wherein said conductive adhesion film includes at least a film selected from a group consisting of a Ti film, a TiN film, a TiAlN film, an Ir film, an IrOₓ film, an IrOₓ film, a Pt film, an Ru film, an RuOₓ film, an Os film and a Ta film.

11. The semiconductor device according to claim 2, wherein said conductive adhesion film is integrated with said conductive pad electrode and is one of an Ir film, an IrOₓ film, an Ru film, an RuOₓ film and an Os film.

12. The semiconductor device according to claim 1, further comprising a conductive protection film electrically isolated from said pad electrode structure and disposed surrounding said pad electrode structure.

13. The semiconductor device according to claim 12, wherein said conductive protection film includes a film of one of Ir, Ru, Rh, Re, Os, oxide thereof and mixture thereof or a lamination thereof.

14. The semiconductor device according to claim 12, wherein said conductive protection film has a layer structure same as said pad electrode structure.

15. The semiconductor device according to claim 12, wherein said conductive protection film is formed covering a whole surface above said semiconductor substrate, excluding an area corresponding to said pad electrode structure.

16. The semiconductor device according to claim 1, further comprising an insulating barrier film disposed in or above said insulating film and including a film made of at least one of aluminum oxide and titanium oxide.

17. The semiconductor device according to claim 16, wherein said insulating barrier film is disposed at a height level crossing said multilayer wiring structure, and covers a whole surface of said semiconductor substrate together with said multilayer wiring structure.

18. The semiconductor device according to claim 17, wherein said multilayer wiring structure includes via conductors and a wiring pattern, and said insulating barrier film is disposed at a height level crossing said wiring pattern.

19. The semiconductor device according to claim 17, wherein said multilayer wiring structure includes via conductors and a wiring pattern, and said insulating barrier film is disposed at a height level crossing said via conductors.

20. The semiconductor device according to claim 16, wherein said insulating barrier film is disposed contacting said pad electrode structure.
